(19) United States
(12) Patent Application Publication
(10) Pub. No.: US 2007/0001785 A1
(43) Pub. Date: Jan. 4, 2007

(54) Surface acoustic wave device

(75) Inventor: Kunihito Yamanaka, Nagano-ken (JP)

Correspondence Address: OLIFF & BERRIDGE, PLC, P.O. BOX 19928, ALEXANDRIA, VA, 22320, US

(73) Assignee: EPSON TOYOCOM CORPORATION, Kanagawa-ken (JP)

(21) Appl. No.: 11/445,256

(22) Filed: Jun. 2, 2006

(30) Foreign Application Priority Data
Jun. 30, 2005 (JP) 2005-164396

(51) Int. Cl. H03H 9/64

(52) U.S. Cl. 333/193

(57) ABSTRACT

The present invention aims to provide a surface acoustic wave (SAW) device including at least two interdigital transducer (IDT) electrodes placed with a predetermined space therebetween on a piezoelectric substrate with improved passband characteristics without increasing the device size.

The device includes IDT electrodes 2 and 3 placed with a predetermined space therebetween on a main surface of a piezoelectric substrate 1 and satisfies the formula:
0<(W/D)*fo/10⁹≦0.6,
where fo is a center frequency measured in Hz, W is the interdigitated length of the IDT electrodes 2 and 3 measured in mm, and D is the distance between the IDT electrodes 2 and 3 measured in mm.

### FIELD OF THE INVENTION

The present invention relates to a surface acoustic wave device including at least two interdigital transducer (IDT) electrodes placed with a predetermined space therebetween on a piezoelectric substrate.

### BACKGROUND TECHNOLOGY

Surface acoustic wave (SAW) filters have been widely employed in the mobile communications field recently. For their desirable properties such as high performance, small size, and high mass productivity, the filters are particularly widely used in cellular phones and wireless local area network (LAN) applications, for example. Intermediate frequency (IF) SAW filters used in these applications need to be small and light-weight, and provide broadband and low-loss characteristics. In addition, a high attenuation level of 50 dB relative to the minimum insertion loss near the passband, for example, may be required to block adjacent carrier frequencies. Among the IF SAW filters that meet these requirements, transversal SAW filters are most suitable.

FIG. 6 is a plan view showing a transversal SAW filter disclosed in JP-A-7-321594 and JP-A-9-270660. IDT electrodes 2 and 3 are placed with a predetermined space therebetween on a piezoelectric substrate 1 along the SAW propagation direction. Each of the IDT electrodes 2 and 3 is made up of a pair of interdigital electrodes having a plurality of electrode fingers interdigitated with each other. One interdigital electrode of the IDT electrode 2 is coupled to an input terminal IN, while the other interdigital electrode thereof is grounded. One interdigital electrode of the IDT electrode 3 is coupled to an output terminal OUT, while the other interdigital electrode thereof is grounded. To suppress unnecessary reflected waves from substrate edges, an acoustic absorbent 5 is applied to the both ends of the piezoelectric substrate 1 in the longitudinal direction (SAW propagation direction). The above-described structure also includes a shield electrode 4 between the IDT electrodes 2 and 3, so that feedthrough caused by electromagnetic coupling between the input and output terminals can be suppressed.

[Patent Document 1] JP-A-7-321594

[Patent Document 2] JP-A-9-270660

### DISCLOSURE OF THE INVENTION

The piezoelectric substrate included in the above-described transversal SAW filter is a quartz crystal substrate in many cases. However, using a quartz crystal substrate with a small electromechanical coupling coefficient for a medium- to broad-band filter whose fractional bandwidth exceeds 2% may cause insertion loss deterioration.

It is possible to prevent the insertion loss deterioration by using lithium tantalate or lithium niobate, which have large electromechanical coupling coefficients. However, since the dielectric constants of lithium tantalate and lithium niobate are about 10 times as large as that of a quartz crystal substrate, electromagnetic coupling between the IDT electrodes becomes stronger. It is therefore difficult to completely suppress effects of feedthrough even if the shield electrode is placed in a space between the IDT electrodes.

FIG. 7 shows passband characteristics of the transversal SAW filter including the piezoelectric substrate made of lithium tantalate. FIG. 7a shows transfer response, while FIG. 7b shows time response. The center frequency of the filter is set at 350 MHz. The aperture length W of the IDT electrodes is 0.75 mm, and the distance D between the IDT electrodes is 0.26 mm. Referring to FIG. 7a showing the transfer response, distortion occurs in the passband of the related art transversal SAW filter and the attenuation level near the passband does not meet 50 dB relative to the minimum insertion loss (0 dB). Referring to FIG. 7b showing the time response, the response around zero on the horizontal delay-time scale indicates the amplitude level of feedthrough caused by electromagnetic coupling between the input and output IDT electrodes. Supposing that an amplitude level of feedthrough relative to the maximum amplitude level (0 dB) of the SAW main response is referred to as a feedthrough level, the feedthrough level of the transversal SAW filter is about −20 dB. To prevent interference between the feedthrough and the SAW main response, it is necessary to suppress the feedthrough level to at least −30 dB or less. Since the related art transversal SAW filter has the large feedthrough level, there arises a problem of interference between the feedthrough and the SAW main response, causing distortion in the passband and the deterioration of attenuation.

As mentioned above, using lithium tantalate or lithium niobate for the piezoelectric substrate included in the related art transversal SAW filter to achieve broadband characteristics may cause interference between the feedthrough and the SAW main response, leading to distortion in the passband and the deterioration of attenuation near the passband. It is therefore necessary to keep the IDT electrodes sufficiently away from each other so as not to cause interference between the feedthrough and the SAW main response.

FIG. 8 shows the relationship of the level of feedthrough to the distance D between the IDT electrodes included in the transversal SAW filter. Here, the piezoelectric substrate is made of lithium tantalate. The aperture length W of the IDT electrodes is 0.75 mm. The center frequency is 310 or 350 MHz. FIG. 8a shows the relationship of the level of feedthrough (dBc) to the distance D (λ) between the input and output IDT electrodes normalized by the SAW wavelength λ. FIG. 8b shows the relationship of the level of feedthrough (dBc) to measured values (mm) of the distance D between the input and output IDT electrodes. As shown here, to provide a feedthrough level of −30 dB or less, the distance D between the input and output IDT electrodes needs to be 47 λ or 0.50 mm or more for a filter whose center frequency is 310 MHz, and to be 45λ or 0.43 mm or more for a filter whose center frequency is 350 MHz. Accordingly, the feedthrough level cannot be −30 dB or less unless the distance D between the input and output IDT electrodes is sufficiently large, resulting in an increased device size.

To address the aforementioned issues, the present invention aims to provide a SAW device including at least two IDT electrodes placed with a predetermined space therebetween that prevents distortion in a passband without increasing the device size and achieves low loss and high attenuation characteristics in a broad bandwidth.

To address the aforementioned issues, a surface acoustic wave (SAW) device according to claim 1 of the invention includes at least two interdigital transducer (IDT) electrodes placed with a predetermined space therebetween on a piezoelectric substrate and satisfies the formula:
0<(W/D)* fo/10⁹≦0.6,
where fo is a center frequency measured in Hz, W is an aperture length W of the IDT electrodes measured in mm, and D is a distance between the IDT electrodes measured in mm.

According to claim 1 of the invention, the SAW device including at least two IDT electrodes placed with a predetermined space therebetween on a piezoelectric substrate and satisfying the formula:
0<(W/D)*fo/10⁹≦0.6,
where fo is a center frequency measured in Hz, W is an aperture length W of the IDT electrodes measured in mm, and D is a distance between the IDT electrodes measured in mm can suppress feedthrough between input and output terminals, prevent distortion in a passband without increasing the device size, and achieve low loss and high attenuation passband characteristics.

According to claim 2 of the invention, the piezoelectric substrate is made of one of lithium tantalate and lithium niobate.

According to claim 2 of the invention, since the piezoelectric substrate according to claim 1 of the invention is made of one of lithium tantalate and lithium niobate, it is possible to provide broad passband characteristics, prevent distortion in a passband without increasing the device size, and achieve low loss and high attenuation passband characteristics.

### BRIEF DESCRIPTION OF THE DRAWINGS

FIG. 1 shows passband characteristics with an aperture length W in a SAW device according to the present invention. FIG. 1a shows characteristics with a center frequency of 310 MHz, while FIG. 1b shows characteristics with a center frequency of 350 MHz.

FIG. 2 shows the relationship of the level of feedthrough to the aperture length W in the SAW device according to the present invention.

FIG. 3 shows the relationship of the level of feedthrough to results from the formula (W/D)*fo/10⁹ as regards the SAW device according to the present invention.

FIG. 4a shows transfer response and FIG. 4b shows time response of the SAW device according to the present invention with a center frequency of 310 MHz.

FIG. 5a shows transfer response and FIG. 5b shows time response of the SAW device according to the present invention with a center frequency of 350 MHz.

FIG. 6 is a plan view of a transversal SAW filter.

FIG. 7a shows transfer response and FIG. 7b shows time response of a related art transversal SAW filter.

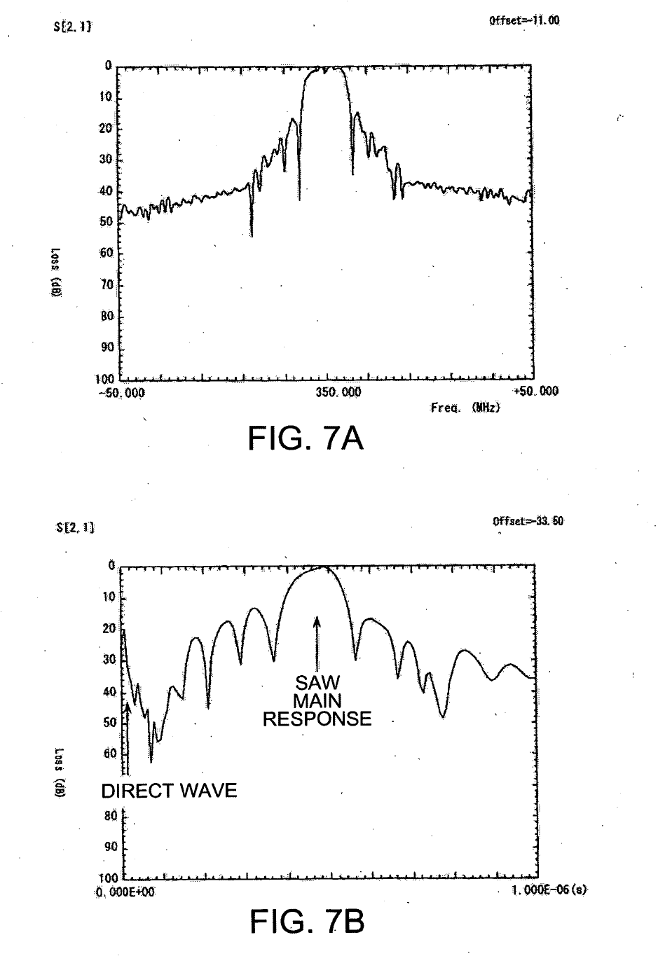

FIG. 8a shows the relationship of the level of feedthrough to the distance D between the IDT electrodes normalized by the wavelength λ of a related art transversal SAW filter. FIG. 8b shows the relationship of the level of feedthrough to measured values of the distance D between the IDT electrodes.

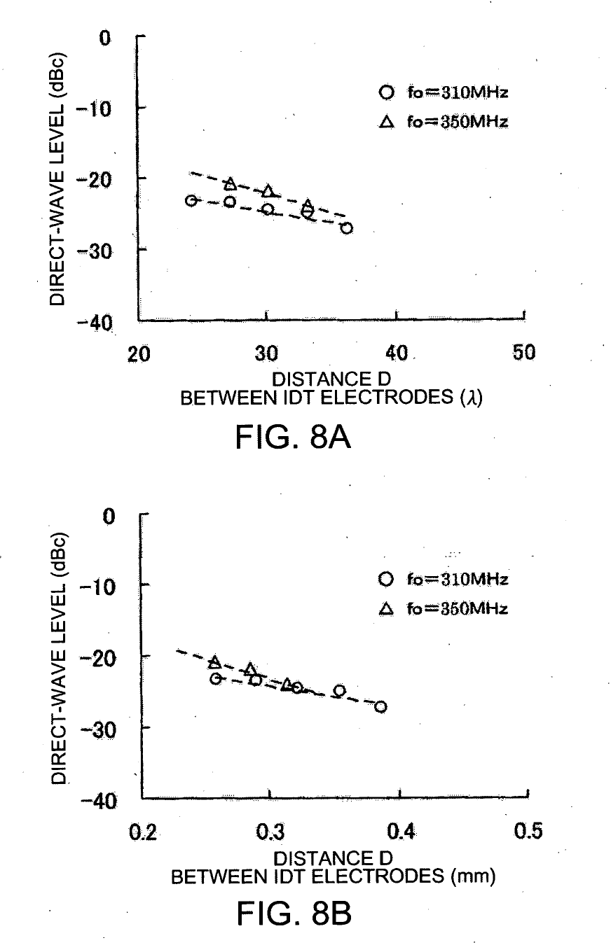

### DESCRIPTION OF PREFERRED EMBODIMENT

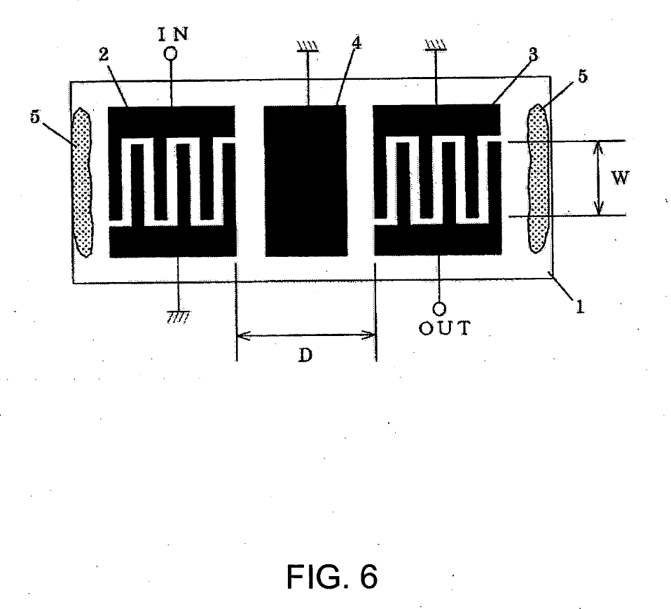

An embodiment of the invention will now be described in detail with reference to the accompanying drawings. A transversal SAW filter according to the invention has basically the same structure as the transversal SAW filter shown in FIG. 6, and includes an input IDT electrode 2 and an output IDT electrode 3 placed with a predetermined space therebetween on a main surface of a piezoelectric substrate 1 along the SAW propagation direction and also includes a shield electrode 4 between the IDT electrodes 2 and 3. Each of the IDT electrodes 2 and 3 is made up of a pair of interdigital electrodes having a plurality of electrode fingers interdigitated with each other. One interdigital electrode of the IDT electrode 2 is coupled to an input terminal IN, while the other interdigital electrode thereof is grounded. One interdigital electrode of the IDT electrode 3 is coupled to an output terminal OUT, while the other interdigital electrode thereof is grounded. To suppress unnecessary reflected waves from substrate edges, an acoustic absorbent 5 is applied to the both ends of the piezoelectric substrate 1 in the longitudinal direction (SAW propagation direction).

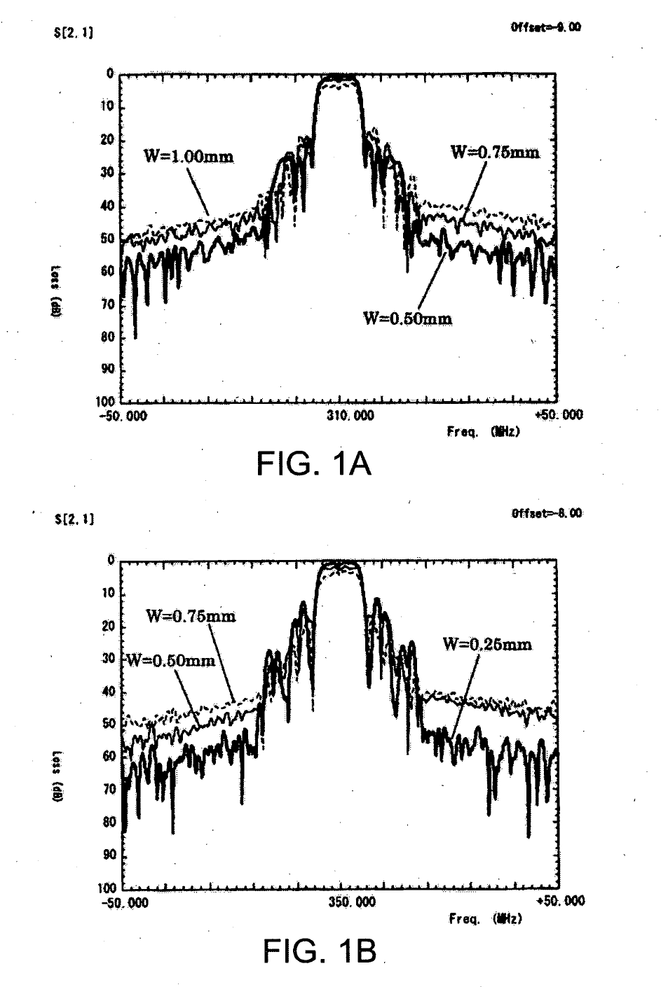

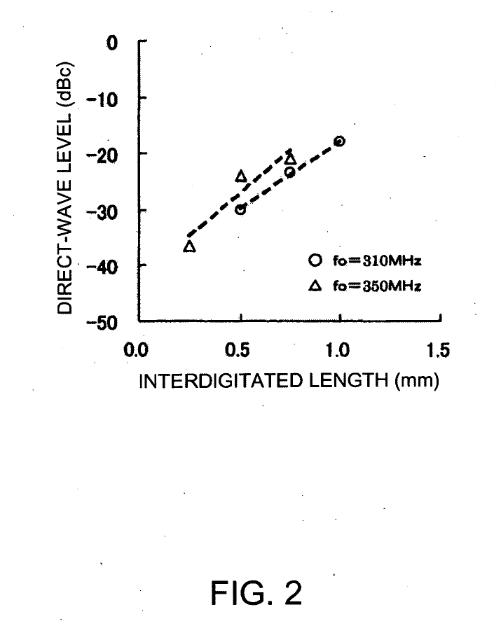

According to the invention, the aperture length W of the IDT electrodes 2 and 3 and the distance D between the IDT electrodes 2 and 3 are optimally set, so that feedthrough caused by electromagnetic coupling between the IDT electrodes 2 and 3 can be suppressed. FIG. 1 shows transfer response of the transversal SAW filter including the piezoelectric substrate made of lithium tantalate. The distance D between the IDT electrodes is set at 0.26 mm, while the aperture length W (mm) is variable. FIG. 1a shows passband characteristics with a center frequency of 310 MHz, while FIG. 1b shows passband characteristics with a center frequency of 350 MHz. As shown here, the less the aperture length W is, the more the distortion in the passband is suppressed for the both frequencies, achieving low loss and high attenuation near the passband. In particular, when W is 0.50 mm for FIG. 1a and W is 0.25 mm for FIG. 1b, a high attenuation level of about 50 dB relative to the minimum insertion loss (0 dB) near the passband is available. FIG. 2 shows the level of feedthrough (dBc) while the aperture length W (mm) is variable as regards the passband characteristics of the transversal SAW filter shown in FIG. 1. As in FIG. 1, the piezoelectric substrate is made of lithium tantalate here. The distance D between the IDT electrodes is 0.26 mm. The center frequency is set at 310 or 350 MHz. The less the aperture length is, the less the level of feedthrough becomes for the both frequencies. When the aperture length W is 0.49 mm or less for the center frequency of 310 MHz and the aperture length W is 0.40 mm or less for the center frequency of 350 MHz, the level of feedthrough can be suppressed to −30 dB or less, thereby preventing interference between the feedthrough and the SAW main response.

As described, the transversal SAW filter according to the invention can suppress the level of feedthrough to −30 dB or less by reducing the aperture length W of the IDT electrodes even if the distance D between the IDT electrodes is 0.26 mm, which is smaller than in related art. Accordingly, it is possible to prevent distortion in the passband without increasing the device size and achieve low loss and high attenuation passband characteristics in a broad bandwidth.

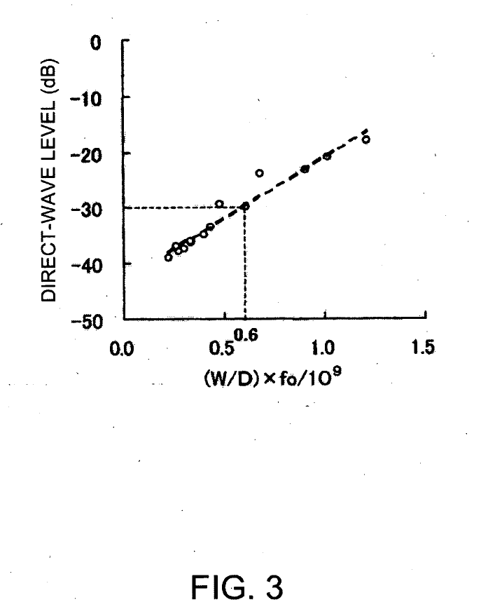

While the distance D between the IDT electrodes is fixed in the above description, the distance D between the IDT electrodes, the aperture length W, and the center frequency fo are complexly variable in the following case. FIG. 3 shows the relationship of the level of feedthrough to results from the formula (W/D)*fo/10⁹, where the center frequency of (Hz), the distance D (mm) between the IDT electrodes, and the aperture length W (mm) are variable. The piezoelectric substrate is made of lithium tantalate. As shown here, the relationship of the level of feedthrough to the results from the formula (W/D)*fo/10⁹ is represented by a near-linear approximation formula. To make the level of feedthrough −30 dB or less, the formula needs to be within the following range:
0<(W/D)*fo/10⁹≦0.6.

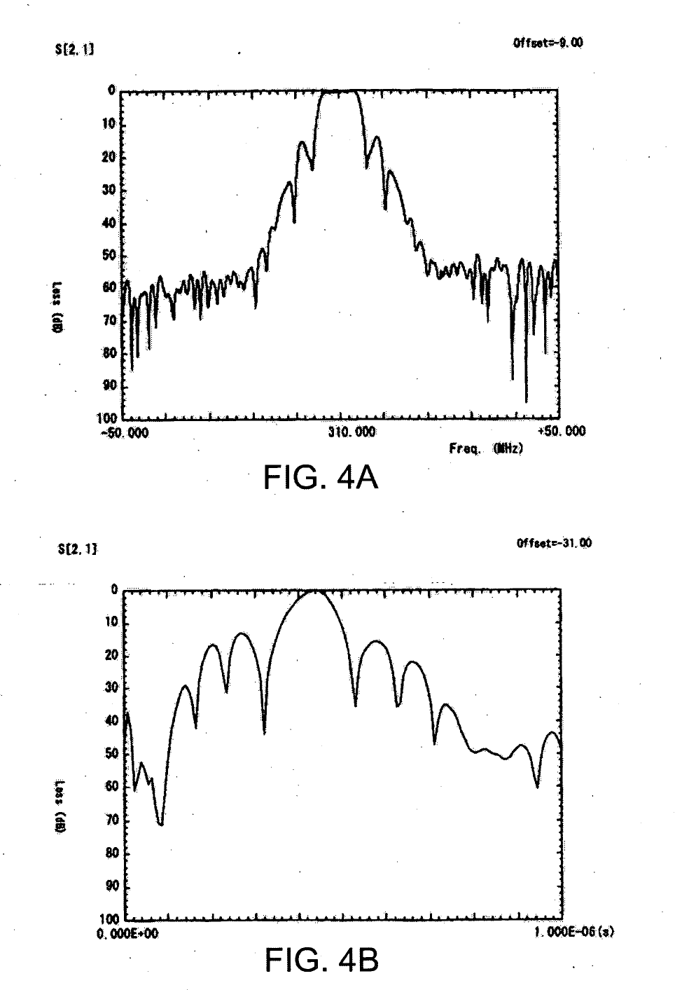

FIG. 4 shows passband characteristics of a filter whose center frequency is 310 MHz when the distance D between the IDT electrodes and the aperture length W are set such that the formula is within the range:
0<(W/D)*fo/10⁹≦0.6.
FIG. 4a shows transfer response, while FIG. 4b shows time response. Here, D is 0.26 mm and W is 0.25 mm. The piezoelectric substrate is made of lithium tantalate. As shown here, the level of feedthrough is suppressed to about −37 dB, achieving low ripple, low loss, and high attenuation passband characteristics.

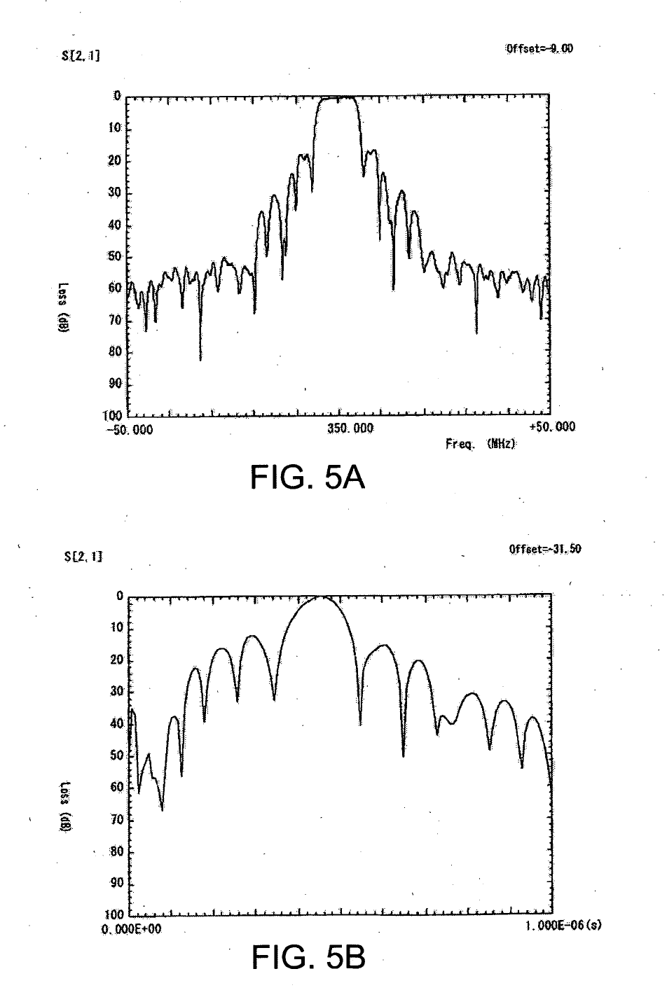

FIG. 5 shows passband characteristics of a filter whose center frequency is 350 MHz when the distance D between the IDT electrodes and the aperture length W are set such that the formula is within the range:
0<(W/D)*fo/10⁹≦0.6.
FIG. 5a shows transfer response, while FIG. 5b shows time response. Here, D is 0.26 mm and W is 0.25 mm. The piezoelectric substrate is made of lithium tantalate. As shown here, the level of feedthrough is suppressed to about −35 dB, achieving low ripple, low loss, and high attenuation passband characteristics.

According to the invention as described above, the SAW device includes at least two IDT electrodes placed with a predetermined space therebetween. By setting the center frequency fo (Hz), the distance D (mm) between the IDT electrodes, and the aperture length W (mm) such that the formula is within the range:
0<(W/D)*fo/10⁹≦0.6,
feedthrough can be sufficiently suppressed, thereby improving passband characteristics without increasing the device size.

While the piezoelectric substrate is made of lithium tantalate in the above description, it has been found that the substrate made of lithium niobate can produce almost the same effects. Moreover, it is understood that other crystal materials, quartz crystal, lithium tetraborate, langasite crystal, for example, are also applicable to the invention. It is also understood that three or more IDT electrodes can be placed on a piezoelectric substrate and other filters than a transversal SAW filter can be used in the invention.

The entire disclosure of Japanese Patent Application No.2005-164396, filed Jun. 3, 2005 is expressly incorporated by reference herein.

1. A surface acoustic wave device, comprising:
at least two interdigital transducer electrodes placed with a predetermined space therebetween on a piezoelectric substrate;
the device satisfying
0<(W/D)*fo/10⁹≦0.6,
where fo is a center frequency measured in Hz, W is an interdigitated length W of the interdigital transducer electrodes measured in mm, and D is a distance between the interdigital transducer electrodes measured in mm.

2. The surface acoustic wave device according to claim 1, wherein the piezoelectric substrate is made of one of lithium tantalate and lithium niobate.
